(19) United States
(12) Patent Application Publication
(10) Pub. No.: US 2013/0015522 A1
(43) Pub. Date: Jan. 17, 2013

(54) SEMICONDUCTOR DEVICE

(71) Applicants: Toshie KUTSUNAI, Toyama (JP); Satoru Ito, Hyogo (JP)

(72) Inventors: Toshie KUTSUNAI, Toyama (JP); Satoru Ito, Hyogo (JP)

(73) Assignee: Panasonic Corporation, Osaka (JP)

(21) Appl. No.: 13/621,115

(22) Filed: Sep. 15, 2012

Related U.S. Application Data
(63) Continuation of application No. PCT/JP2011/001583, filed on Mar. 17, 2011.

(30) Foreign Application Priority Data
Jul. 7, 2010 (JP) 2010-154558

(51) Int. Cl. H01L 27/092

(52) U.S. Cl. 257/338; 257/E27.062

(57) ABSTRACT

A semiconductor device includes an active region formed in a semiconductor substrate made of silicon, and surrounded by an isolation region; and a gate electrode formed on the active region and the isolation region with a gate insulating film interposed between the gate electrode and the active region or the isolation region. P-type silicon alloy layers are formed in recess regions formed in regions of the active region located laterally outward of the gate electrode, and an upper end of a portion of each of the silicon alloy layers in contact with the isolation region is located below a portion of an upper surface of the active region under the gate insulating film.

### CROSS-REFERENCE TO RELATED APPLICATIONS

This is a continuation of PCT International Application PCT/JP2011/001583 filed on Mar. 17, 2011, which claims priority to Japanese Patent Application No. 2010-154558 filed on Jul. 7, 2010. The disclosures of these applications including the specifications, the drawings, and the claims are hereby incorporated by reference in their entirety.

### BACKGROUND

The present disclosure relates to semiconductor devices and methods for fabricating the same, and more particularly relates to a semiconductor device having an active region including a silicon alloy layer, and a method for fabricating the same.

In recent years, with advances in information communication devices, higher performance has been required of semiconductor devices, such as system large scale integration (LSI) circuits. Therefore, the operating speeds of transistors have been increased. For example, complementary metal insulator semiconductor (CMIS) transistors including an n-type metal insulator semiconductor (MIS) transistor and a p-type MIS transistor consume low power, and thus, have been widely used, and increases in the speeds of the transistors result mainly from miniaturization of the transistor structures. Specifically, increases in the speeds of CMIS transistors are supported by advances in a lithography technique for processing semiconductor elements. However, in recent years, the smallest required feature size has been equal to or smaller than the wavelength of light used for lithography, and consequently, it is becoming difficult to further miniaturize CMIS transistors.

To address this difficulty, a need has existed for technologies for improving the performance of transistors without miniaturizing the transistor structures. Examples of the technologies include strained silicon technology in which the mobility of carriers is enhanced by straining a silicon crystal. A transistor using the strained silicon technology may provide higher carrier mobility than a transistor made of bulk silicon. Thus, the performance of such a transistor using strained silicon technology can be improved without miniaturizing the transistor structure.

It has been known that the use of the strained silicon technology improves the current driving capability of CMIS transistors, and attention has been given to the following technique. Specifically, when a material having a larger lattice constant than silicon is embedded in source/drain regions of a p-type MIS transistor formation region of a CMIS transistor formed on a semiconductor substrate made of silicon (Si), compressive stresses are applied to a channel region of a corresponding p-type MIS transistor. This can improve the carrier mobility of the p-type MIS transistor. To be more specific, the source/drain regions of the p-type MIS transistor formation region of the CMIS transistor are made of a silicon alloy, such as silicon germanium (SiGe), having a larger lattice constant than silicon. This allows application of compressive stresses to a silicon crystal forming the channel region of the p-type MIS transistor, thereby increasing the carrier mobility (mobility of holes) of the p-type MIS transistor. This increase in the carrier mobility can improve the current driving capability of the p-type MIS transistor of the CMIS transistor.

A semiconductor device including a p-type MIS transistor fabricated using a conventional strained silicon technology will be described hereinafter with reference to FIGS. 8 and 9A-9D.

As illustrated in FIGS. 8 and 9A-9D, a conventional semiconductor device includes first and second active regions 110a and 110b surrounded by an isolation region 111 formed in an upper portion of a semiconductor substrate 110, and arranged along the channel width. A p-type well region 112a is formed in the first active region 110a, and an n-type well region 112b is formed in the second active region 110b. Thus, an n-type MIS transistor including the p-type well region 112a is formed on the first active region 110a forming an n-type MIS transistor formation region NTr of the semiconductor substrate 110, and a p-type MIS transistor including the n-type well region 112b is formed on the second active region 110b forming a p-type MIS transistor formation region PTr of the semiconductor substrate 110.

The n-type MIS transistor on the n-type MIS transistor formation region NTr includes a gate insulating film 113 and a gate electrode 114 sequentially formed on the first active region 110a, and sidewalls 118 formed on both lateral side surfaces of the gate electrode 114. The sidewalls 118 each include an inner sidewall 116 and an outer sidewall 117. Specifically, the inner sidewall 116 is formed on each of the lateral side surfaces of the gate electrode 114, and the outer sidewall 117 is formed on each of the lateral side surfaces of the gate electrode 114 with the inner sidewall 116 interposed therebetween. N-type extension regions 115a are formed in regions of an upper portion of the first active region 110a located laterally outward of the gate electrode 114, and n-type source/drain regions 119a are formed immediately outward of the n-type extension regions 115a and laterally outward of the sidewalls 118. Here, a silicide layer 112 is formed in each of an upper portion of the gate electrode 114 and upper portions of the n-type source/drain regions 119a. In FIG. 8, the silicide layer 112 is not shown.

The p-type MIS transistor on the p-type MIS transistor formation region PTr includes a gate insulating film 113 and a gate electrode 114 sequentially formed on the second active region 110b, and sidewalls 118 formed on both lateral side surfaces of the corresponding gate electrode 114. The sidewalls 118 on the p-type MIS transistor formation region PTr have the same structure as the sidewalls 118 on the n-type MIS transistor formation region NTr. P-type extension regions 115b are formed in regions of an upper portion of the second active region 110b located laterally outward of the corresponding gate electrode 114, and p-type source/drain regions 119b are formed immediately outward of the p-type extension regions 115b and laterally outward of the corresponding sidewalls 118.

Furthermore, as illustrated in FIGS. 9A and 9D, p-type silicon germanium (SiGe) layers 121 are formed on the p-type source/drain regions 119b by epitaxial growth. In this case, a central portion of each of the SiGe layers 121 and a portion thereof at the interface between the SiGe layer 121 and the isolation region 111 have substantially the same thickness, and an upper surface of the SiGe layer 121 at the interface between the SiGe layer 121 and the isolation region 111 is located above an upper surface of the isolation region 111. This allows a portion of a side surface of the isolation region 111 located toward the interface between the isolation region 111 and the SiGe layer 121, and including an upper end of the side surface to be in contact with the SiGe layer 121. Similar to the n-type MIS transistor, a silicide layer 122 is formed in each of an upper portion of the corresponding gate electrode 114 and upper portions of the p-type SiGe layers 121.

### SUMMARY

As in the semiconductor device according to the conventional example, a CMIS transistor includes an n-type MIS transistor and a p-type MIS transistor. Therefore, in the CMIS transistor, both of the n-type MIS transistor and the p-type MIS transistor preferably exhibit high current driving capability.

Incidentally, as illustrated in FIG. 8, a CMIS transistor usually includes an isolation region formed to surround MIS transistors. Therefore, in a p-type MIS transistor, stresses are applied from an isolation region to SiGe layers and from the SiGe layers to the isolation region, at the boundaries between the isolation region and the SiGe layers, and thus, stress concentration regions are formed at the boundaries, thereby causing complicated strains. The stresses exhibit complicated behaviors via heat treatment in a fabrication process due to the difference in coefficient of thermal expansion between silicon (Si) forming an active region and a silicon dioxide (SiO₂) film forming the isolation region. Furthermore, the strains cause abnormal diffusion of dopants by heat treatment at low temperatures. Therefore, with a reduction in the gate length, leakage currents flowing through end portions of a region of the active region under a gate electrode increase.

Specifically, forces in the directions in which the active region pushes the isolation region outward act on the interfaces between end portions of the active region in the gate width direction and the isolation region by stresses from the SiGe layers. However, no SiGe layer is formed under the gate electrode, and thus, forces in the directions in which the active region and the isolation region are separated from each other act on the interfaces between the end portions of the region of the active region under the gate electrode and the isolation region. As a result, the interface state density between the active region and the isolation region increases, the leakage current between adjacent p-type source/drain regions, in particular, during standby increases by the phenomenon where diffusion of impurities with which the p-type source/drain regions are doped is accelerated at high temperatures, and the phenomenon where carriers travel via interface states.

An object of the present disclosure is to solve the above problems, and provide a semiconductor device which has an active region including a silicon alloy layer configured to apply stresses to a channel region, and which achieves an improvement in current driving capability and a reduction in leakage current.

In order to achieve the above object, the present disclosure provides a semiconductor device configured such that silicon alloy layers are formed in an active region, and an upper end of a portion of each of the silicon alloy layers in contact with an isolation region surrounding the silicon alloy layers is located below an upper surface of the active region (a portion of the upper surface thereof under a gate electrode).

Specifically, a semiconductor device according to the present disclosure includes: a first active region formed in a semiconductor region made of silicon, and surrounded by an isolation region; and a first gate electrode formed on the first active region and the isolation region with a first gate insulating film interposed between the first gate electrode and a portion of the semiconductor region including the first active region and the isolation region. Silicon alloy layers of a first conductivity type are formed in recesses formed in regions of the first active region located laterally outward of the first gate electrode, and an upper end of a portion of each of the silicon alloy layers in contact with the isolation region is located below a portion of an upper surface of the first active region under the first gate insulating film.

According to the semiconductor device of the present disclosure, the upper end of the portion of each of the silicon alloy layers in contact with the isolation region is located below the portion of the upper surface of the first active region under the first gate insulating film, thereby reducing the contact area between the silicon alloy layer and the isolation region. This reduces forces applied in directions in which the first active region pushes the isolation region outward by stresses from the silicon alloy layers at the interfaces between end portions of the first active region in the gate width direction and the isolation region. As a result, forces applied in directions in which the first active region and the isolation region are separated from each other are also reduced, and thus, for example, diffusion of impurities with which the first active region is doped, and migration of carriers via interface states are reduced, thereby improving current driving capability, and reducing leakage current.

In the semiconductor device of the present disclosure, a side surface of each of the silicon alloy layers near the first gate electrode preferably has a protrusion protruding below the first gate electrode, and the upper end of the portion of each of the silicon alloy layers in contact with the isolation region is preferably located below the protrusion.

This further ensures that the protrusions formed on opposed surfaces of the silicon alloy layers near the first gate electrode apply stresses to a channel region in the gate length direction while reducing stresses form the silicon alloy layers to the isolation region.

In this case, an upper surface of the semiconductor region may have a {100} plane orientation, and a surface of each of the silicon alloy layers forming the protrusion may have a {111} plane orientation.

In the semiconductor device of the present disclosure, the upper end of the portion of each of the silicon alloy layers in contact with the isolation region may be located below one half of a depth of a thickest portion of the silicon alloy layer from a top surface of the silicon alloy layer.

This can ensure a reduction in the contact area between the silicon alloy layer and the isolation region.

In the semiconductor device of the present disclosure, the silicon alloy layers may be formed as first source/drain regions, the semiconductor device may further include extension regions having the first conductivity type, and formed in regions of an upper portion of the first active region located laterally outward of the first gate electrode so as to be connected to the first source/drain regions, and the upper end of the portion of each of the silicon alloy layers in contact with the isolation region may be located below the extension regions.

The semiconductor device of the present disclosure may further include: sidewalls formed on both side surfaces of the first gate electrode in a gate length direction, and made of an insulating film.

In the semiconductor device of the present disclosure, the silicon alloy layers of the first conductivity type are preferably made of p-type silicon germanium.

This allows the semiconductor device to be a p-type transistor to which compressive stresses are applied from both sides of the channel region in the gate length direction.

In this case, the semiconductor device of the present disclosure may further include: a second active region formed in the semiconductor region with the isolation region interposed between the first and second active regions; and a second gate electrode formed on the second active region and the isolation region with a second gate insulating film interposed between the second gate electrode and a portion of the semiconductor region including the second active region and the isolation region, and second source/drain regions each made of an impurity diffusion layer of a second conductivity type may be formed in an upper portion of the second active region.

In the semiconductor device of the present disclosure, the silicon alloy layers of the first conductivity type may be made of n-type silicon carbide.

This allows the semiconductor device to be an n-type transistor to which tensile stresses are applied from both sides of the channel region in the gate length direction.

In the semiconductor device of the present disclosure, an upper surface of a thickest portion of each of the silicon alloy layers may be located above the portion of the upper surface of the first active region under the first gate insulating film.

Thus, stresses applied to the channel region formed under the first gate electrode can be reliably produced.

A method for fabricating a semiconductor device according to the present disclosure includes: forming an active region by selectively forming an isolation region in a semiconductor region; forming a gate electrode on the active region and the isolation region with a gate insulating film interposed between the gate electrode and a portion of the semiconductor region including the active region or the isolation region; forming recesses in regions of the active region located laterally outward of the gate electrode by etching the active region using at least the gate electrode as a mask; and forming a silicon alloy layer of a first conductivity type in each of the recesses, and an upper end of a portion of the silicon alloy layer in contact with the isolation region is located below a portion of an upper surface of the active region under the gate insulating film.

According to the method of the present disclosure, the upper end of the portion of each of the silicon alloy layers in contact with the isolation region is located below the portion of the upper surface of the active region under the gate insulating film, thereby reducing the contact area between the silicon alloy layer and the isolation region. This reduces forces applied in directions in which the active region pushes the isolation region outward by stresses from the silicon alloy layers at the interfaces between end portions of the active region in the gate width direction and the isolation region. As a result, forces applied in directions in which the active region and the isolation region are separated from each other are also reduced, and thus, for example, diffusion of impurities with which the active region is doped, and migration of carriers via interface states are reduced, thereby improving current driving capability, and reducing leakage current.

The method of the present disclosure may further include: between the forming of the gate electrode and the forming of the recesses, forming extension regions in an upper portion of the active region by implanting an impurity of the first conductivity type into the active region using the gate electrode as a mask; after the forming of the extension regions, forming sidewalls made of an insulating film on both side surfaces of the gate electrode in a gate length direction; and implanting an impurity of the first conductivity type into the active region using the gate electrode and the sidewalls as masks, thereby forming source/drain regions in the upper portion of the active region to each have a deeper junction depth than the extension regions.

In the method of the present disclosure, the silicon alloy layer of the first conductivity type is preferably made of p-type silicon germanium.

According to the semiconductor device of the present disclosure, when the silicon alloy layers applying stresses to the channel region are formed in the active region, this can achieve an improvement in current driving capability and a reduction in leakage current.

### BRIEF DESCRIPTION OF THE DRAWINGS

FIG. 1 is a plan view illustrating a semiconductor device according to an embodiment of the present disclosure.

FIG. 2A is a cross-sectional view taken along the line IIa-IIa in FIG. 1, FIG. 2B is a cross-sectional view taken along the line IIb-IIb in FIG. 1, FIG. 2C is a cross-sectional view taken along the line IIc-IIc in FIG. 1, and FIG. 2D is a cross-sectional view taken along the line IId-IId in FIG. 1.

FIG. 3A is a cross-sectional view taken along the line IIIa-IIIa in FIG. 1, and FIG. 3B is a cross-sectional view taken along the line IIIb-IIIb in FIG. 1.

FIGS. 4A1 and 4B1 are cross-sectional views sequentially illustrating process steps in a method for fabricating a semiconductor device according to the embodiment of the present disclosure, and corresponding to the cross section of the structure of the semiconductor device taken along the line IIc-IIc in FIG. 1. FIGS. 4A2 and 4B2 are cross-sectional views sequentially illustrating process steps in the method for fabricating a semiconductor device according to the embodiment of the present disclosure, and corresponding to the cross section of the structure of the semiconductor device taken along the line IId-IId in FIG. 1.

FIGS. 5A1 and 5B1 are cross-sectional views sequentially illustrating process steps in the method for fabricating a semiconductor device according to the embodiment of the present disclosure, and corresponding to the cross section of the structure of the semiconductor device taken along the line IIc-IIc in FIG. 1. FIGS. 5A2 and 5B2 are cross-sectional views sequentially illustrating process steps in the method for fabricating a semiconductor device according to the embodiment of the present disclosure, and corresponding to the cross section of the structure of the semiconductor device taken along the line IId-IId in FIG. 1.

FIG. 6 is a cross-sectional view illustrating a variation of an etching process for recess regions in which silicon alloy layers are formed in the method for fabricating a semiconductor device according to the embodiment of the present disclosure.

FIG. 7 is a graph illustrating the dependency of off-state leakage current from a source of each of the semiconductor device according to the embodiment of the present disclosure and a semiconductor device according to a conventional example on the gate length.

FIG. 8 is a plan view illustrating a conventional semiconductor device.

FIG. 9A is a cross-sectional view taken along the line IXa-IXa in FIG. 8, FIG. 9B is a cross-sectional view taken along the line IXb-IXb in FIG. 8, FIG. 9C is a cross-sectional view taken along the line IXc-IXc in FIG. 8, and FIG. 9D is a cross-sectional view taken along the line IXd-IXd in FIG. 8.

### DETAILED DESCRIPTION

An embodiment of the present disclosure will be described. The present disclosure is not limited to the following embodiment. For example, components of a semiconductor device are not limited to the following components, and film thicknesses, concentrations, etc., are also not limited to the following numeric values. For example, film formation processes and etching processes are also not limited to the following processes.

### Embodiment

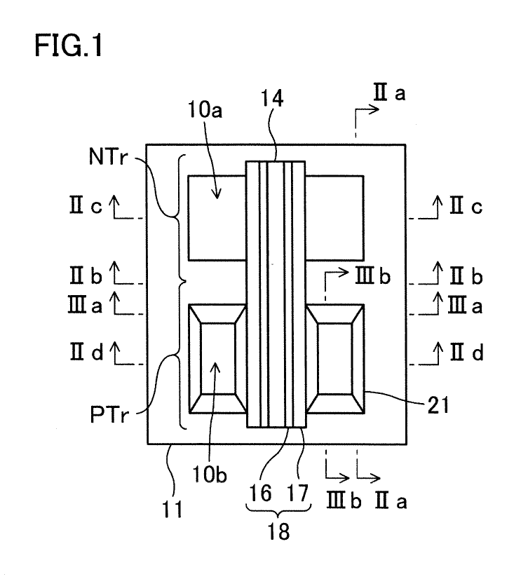

A semiconductor device according to an embodiment of the present disclosure will be described with reference to FIGS. 1-3.

As illustrated in FIGS. 1, 2A-2D, 3A, and 3B, the semiconductor device according to this embodiment includes first and second active regions 10a and 10b surrounded by an isolation region 11 formed in an upper portion of a semiconductor substrate 10 and arranged along the channel width. A p-type well region 12a is formed in the first active region 10a, and an n-type well region 12b is formed in the second active region 10b. Thus, an n-type MIS transistor including the p-type well region 12a is formed on the first active region 10a forming an n-type MIS transistor formation region NTr of the semiconductor substrate 10, and a p-type MIS transistor including the n-type well region 12b is formed on the second active region 10b forming a p-type MIS transistor formation region PTr of the semiconductor substrate 10.

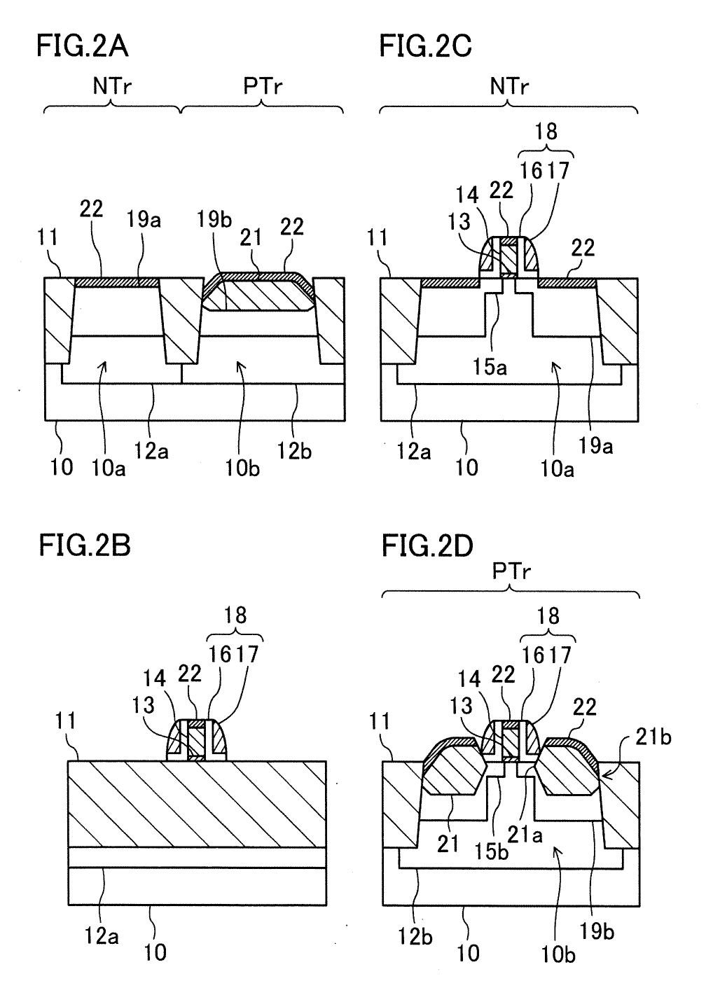

As illustrated in FIGS. 1, 2A, and 2C, the n-type MIS transistor on the n-type MIS transistor formation region NTr includes a gate insulating film 13 and a gate electrode 14 sequentially formed on the first active region 10a, and sidewalls 18 formed on both lateral side surfaces of the gate electrode 14 and each including two insulating films. For example, the sidewalls 18 each include an inner sidewall 16 and an outer sidewall 17. Specifically, the inner sidewall 16 having an L-shaped cross section is formed on each of the lateral side surfaces of the gate electrode 14, and the outer sidewall 17 is formed on each of the lateral side surfaces of the gate electrode 14 with the inner sidewall 16 interposed therebetween.

N-type extension regions 15a are formed in regions of an upper portion of the first active region 10a located laterally outward of the gate electrode 14. Furthermore, n-type source/drain regions 19a each having a deeper junction depth than the n-type extension regions 15a are formed in regions of the first active region 10a located laterally outward of the n-type extension regions 15a so as to be connected to the n-type extension regions 15a. A silicide layer 22 is formed in each of an upper portion of the gate electrode 14 and upper portions of the n-type source/drain regions 19a. In FIG. 1, the silicide layer 22 is not shown.

Here, for example, about 2-4-nm-thick silicon dioxide (SiO₂) can be used as a material of the gate insulating film 13. For example, about 50-100-nm-thick polysilicon can be used as a material of the gate electrode 14. For example, silicon dioxide can be used as a material of the inner sidewall 16, and, for example, silicon nitride (SiN) can be used as a material of the outer sidewall 17. A high dielectric constant insulating film called a high-k film, such as hafnium dioxide (HfO₂) having a dielectric constant greater than or equal to 8, or nitridated hafnium silicate (HfSiON), may be used as a material of the gate insulating film 13, and in this case, a multilayered film including a metal film made of, e.g., tantalum nitride (TaN) or titanium nitride (TiN), and formed on the gate insulating film 13, and a silicon film made of, e.g., polysilicon, and formed on the metal film is preferably used as a material of the gate electrode 14.

The n-type extension regions 15a are doped with n-type impurities, such as arsenic (As), and the dose of the n-type impurities is about 1×10¹⁵-1×10¹⁶/cm². The n-type source/drain regions 19a are also doped with n-type impurities, such as arsenic (As), and the dose of the n-type impurities is about 1×10¹⁶/cm². The silicide layer 22 is made of, e.g., about 20-nm-thick nickel silicide (NiSi).

As illustrated in FIGS. 1, 2A, and 2D, the p-type MIS transistor on the p-type MIS transistor formation region PTr includes a gate insulating film 13 and a gate electrode 14 sequentially formed on the second active region 10b, and respectively made of the same materials as the gate insulating film 13 and the gate electrode 14 of the n-type MIS transistor. Sidewalls 18 are formed on both lateral side surfaces of the gate electrode 14, and each include an inner sidewall 16 and an outer sidewall 17 which respectively have the same structures as the inner sidewall 16 and the outer sidewall 17 of the n-type MIS transistor.

P-type extension regions 15b are formed in regions of an upper portion of the second active region 10b located laterally outward of the corresponding gate electrode 14. Furthermore, p-type source/drain regions 19b each having a deeper junction depth than the p-type extension regions 15b are formed in regions of the second active region 10b laterally outward of the p-type extension regions 15b so as to be connected to the p-type extension regions 15b. Similar to the n-type MIS transistor, a silicide layer 22 is formed in an upper portion of the corresponding gate electrode 14.

The p-type extension regions 15b are doped with p-type impurities, such as boron (B), and the dose of the p-type impurities is about 1×10¹⁵-1×10¹⁶/cm². The p-type source/drain regions 19b are also doped with p-type impurities, such as boron (B), and the dose of the p-type impurities is, e.g., about 1×10¹⁶/cm².

Furthermore, as illustrated in FIG. 2D, in the p-type MIS transistor, p-type silicon alloy layers 21 are formed in upper portions of the p-type source/drain regions 19b by epitaxial growth so that the uppermost surfaces (upper surfaces at the highest level) of the layers 21 are located above the principal surface of the semiconductor substrate 10 (the surface of the semiconductor substrate 10 immediately below the gate insulating film 13).

The p-type silicon alloy layers 21 are made of a silicon alloy (e.g., SiGe) having a larger lattice constant than silicon (Si), and induce compressive stresses along the gate length. The p-type silicon alloy layers 21 each have a thickness of about 120 nm, and contain germanium (Ge) in a weight ratio of about 20-30% relative to silicon (Si). At least a side surface of each of the p-type silicon alloy layers 21 located near the gate electrode 14 has a {111} plane orientation of a silicon crystal, and includes a protrusion 21 a protruding toward the corresponding gate electrode 14. The protrusion 21a, and a protruding portion of the wall surface of a recess region (described below) for forming the protrusion 21a are hereinafter referred to also as a Σ-shaped distal end portion.

The p-type silicon alloy layers 21 are also doped with p-type impurities, such as boron (B), at a dose of, e.g., about 1×10¹⁶/cm². Specifically, the concentration of the p-type impurities in each of the p-type silicon alloy layers 21 is preferably approximately identical with that of the p-type impurities in each of the p-type source/drain regions 19b. Since, as such, the p-type silicon alloy layers 21 are formed in the upper portions of the p-type source/drain regions 19b, compressive stresses are applied to a channel region of the p-type MIS transistor along the gate length. This can improve the carrier mobility (mobility of holes) of the p-type MIS transistor. Therefore, in this embodiment, the current driving capability of the p-type MIS transistor can be enhanced. As illustrated in FIG. 2C, the p-type silicon alloy layers 21 are formed only in the p-type source/drain regions 19b, and silicon alloy layers are not formed in the n-type source/drain regions 19a of the n-type MIS transistor.

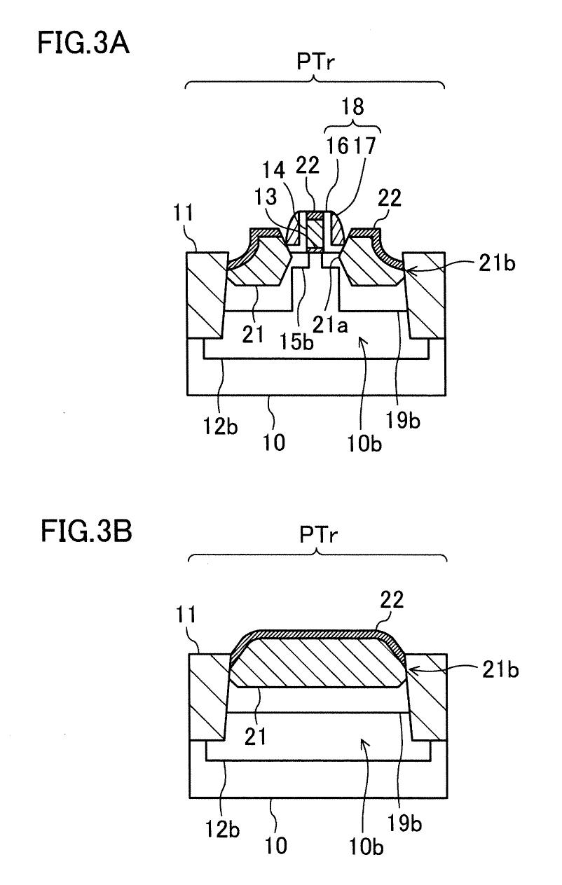

A feature of this embodiment is that as illustrated in FIGS. 3A and 3B, in the semiconductor device of this embodiment, an upper end 21b of a portion of each of the p-type silicon alloy layers 21 in contact with the isolation region 11 at the interface between the portion and the isolation region 11 is located below a portion of an upper surface of the second active region 10b under the gate insulating film 13. In addition, in the semiconductor device of this embodiment, the upper end 21b is located below the protrusion 21a which is the Σ-shaped distal end portion. Furthermore, the upper end 21b is located below one half of the depth of the thickest portion of the p-type silicon alloy layer 21 from the top surface thereof. The upper end 21b is located below the junction interface between the p-type silicon alloy layer 21 and the corresponding p-type extension region 15b. The upper end 21b is located below an upper surface of the isolation region 11, the p-type silicon alloy layers 21 do not cover upper portions of side surfaces of the isolation region 11 located near the interfaces between the isolation region 11 and the p-type silicon alloy layers 21, and the upper portions of the side surfaces of the isolation region 11 located near the interfaces are not in contact with the p-type silicon alloy layers 21. In contrast, the height of an upper surface of each of the p-type silicon alloy layers 21 increases from the isolation region 11 toward the inside, i.e., center, of the second active region 10b. In the present disclosure, each of the p-type silicon alloy layers 21 does not include the silicide layer 22 formed thereon.

As described above, the p-type silicon alloy layers 21 formed in the upper portions of the p-type source/drain regions 19b of the p-type MIS transistor are semiconductor films inducing compressive stresses on the channel region along the gate length.

In this embodiment, as illustrated in FIGS. 2D and 3A, the surface of each of the p-type silicon alloy layers 21 forms a facet, and thus, is inclined relative to the substrate surface. The reason for this is that when the p-type silicon alloy layers 21 are epitaxially grown, the surface with a low-index plane orientation preferentially forms a facet so that the surface energy of a crystal is minimum. In order to reduce the thickness of a portion of each of the p-type silicon alloy layers 21 at the interface between the p-type silicon alloy layer 21 and the isolation region 11, for example, the deposition rate during the growth may be decreased, and the supply of hydrogen chloride (HCl) may be increased. Specifically, the growth rate of each of the p-type silicon alloy layers 21 at the interface between the p-type silicon alloy layer 21 and the isolation region 11 depends on either of the formation of a facet and the deposition rate in response to the conditions where the p-type silicon alloy layer 21 is grown. Therefore, when such conditions where the surface with a {111} plane orientation of a silicon crystal is formed are used, the growth rate of the p-type silicon alloy layer 21 can be decreased, thereby reducing the thickness of the portion of the p-type silicon alloy layer 21 at the interface between the p-type silicon alloy layer 21 and the isolation region 11. This reduces the density of nuclei formed at the interface between the p-type silicon alloy layer 21 and the isolation region 11 in the p-type silicon alloy layer 21 according to this embodiment, thereby reducing the thickness of the portion of the p-type silicon alloy layer 21.

As such, in the p-type MIS transistor of this embodiment, compressive stresses applied from the p-type silicon alloy layers 21 formed in the p-type source/drain regions 19b to the isolation region 11 can be reduced.

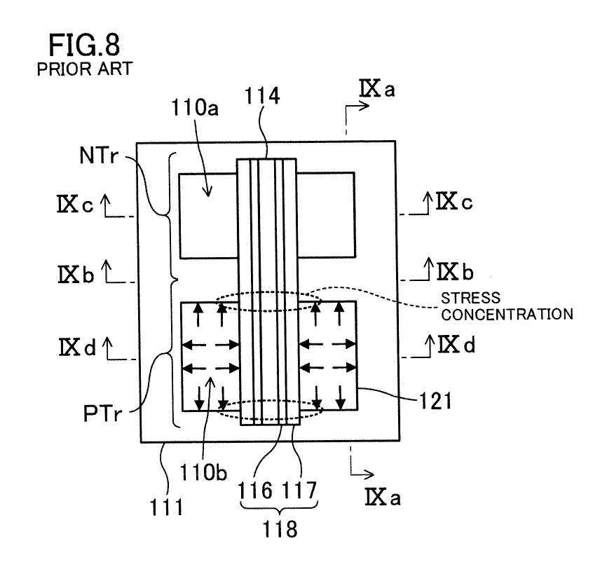

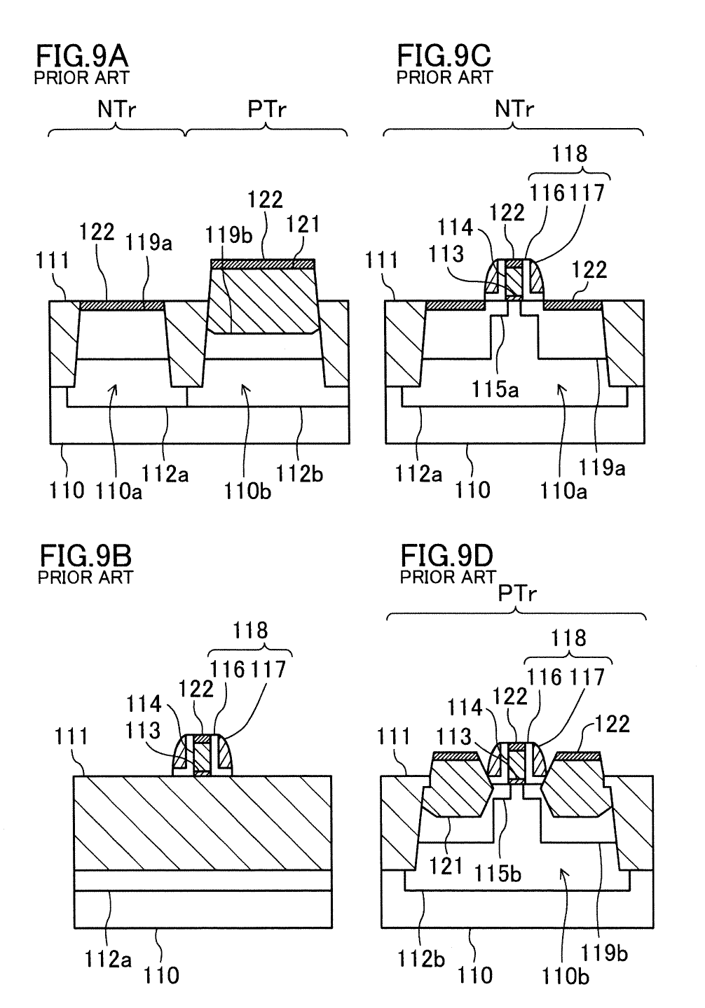

This advantage will be described hereinafter with a comparison between a conventional semiconductor device illustrated in FIGS. 8 and 9A-9D and the semiconductor device of this embodiment.

Since, in the conventional semiconductor device, p-type SiGe layers 121 are formed in p-type source/drain regions 119b of a p-type MIS transistor, compressive stresses are applied to a channel region of the p-type MIS transistor along the gate length. This can improve the carrier mobility of the p-type MIS transistor. However, stresses applied from the p-type SiGe layers 121 inducing compressive stresses to an isolation region 111 cannot be reduced. This causes abnormal diffusion of dopants into the p-type MIS transistor, resulting in an increase in off-state leakage current from a source of the p-type MIS transistor.

In contrast, similar to the conventional semiconductor device, the semiconductor device according to this embodiment includes the p-type silicon alloy layers 21 formed in the p-type source/drain regions 19b of the p-type MIS transistor. However, in this embodiment, the upper end 21b of the portion of each of the p-type silicon alloy layers 21 in contact with the isolation region 11 is located below the portion of the upper surface of the second active region 10b under the gate electrode 14, and in other words, the thickness of the portion of the p-type silicon alloy layer 21 in contact with the isolation region 11 is reduced.

As such, in this embodiment, at least some of stresses from the isolation region 11 can be canceled by reducing the thickness of a corresponding end portion of each of the p-type silicon alloy layers 21. Specifically, application of combined stresses from the p-type silicon alloy layers 21 and the isolation region 11 to the channel region of the p-type MIS transistor can be reduced.

Therefore, the semiconductor device according to this embodiment cannot only improve the current driving capability of the p-type MIS transistor, but also reduce an increase in the off-state leakage current from the source of the p-type MIS transistor.

The upper end 21b of the portion of each of the p-type silicon alloy layers 21 in contact with the isolation region 11 is preferably below the protrusion 21a near the gate electrode 14.

When consideration is given to the fact that the silicide layers 22 each have a thickness of about 20 nm, and the p-type silicon alloy layers 21 each have a thickness of about 120 nm, the depth from an upper surface of the isolation region 11 to the upper end 21b of the portion of each of the p-type silicon alloy layers 21 in contact with the isolation region 11 may be about 10-60 nm. This can prevent application of stresses from the isolation region 11 to the channel region of the p-type MIS transistor while ensuring insulation between the first and second active regions 10a and 10b.

In summary, the semiconductor device according to this embodiment includes the p-type silicon alloy layers 21 formed in the p-type source/drain regions 19b of the p-type MIS transistor, and furthermore, the portion of each of the p-type silicon alloy layers 21 in contact with the isolation region 11 is thin. In other words, the height of the surface of the p-type silicon alloy layer 21 increases from the end thereof in contact with the isolation region 11 toward a center portion of the second active region 10b. This can improve the current driving capability of the p-type MIS transistor, and reduce leakage current through the p-type MIS transistor during standby.

(Fabrication Method of Embodiment)

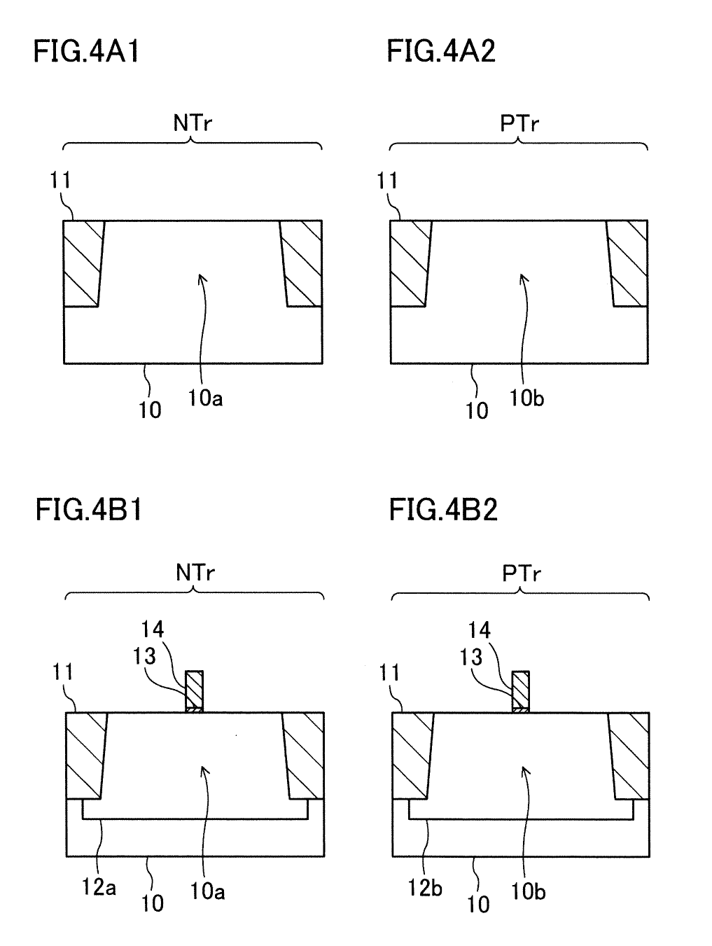

A method for fabricating a semiconductor device configured as described above will be described hereinafter with reference to FIGS. 4A1-5B2.

First, in a process step illustrated in FIGS. 4A1 and 4A2, a resist mask (not shown) having a pattern for forming an isolation region is formed on a semiconductor substrate 10, e.g., by lithography, and the semiconductor substrate 10 is etched using the formed resist mask, thereby forming an about 200-300-nm-deep trench. Thereafter, an about 100-150-nm-thick silicon dioxide film is deposited on the semiconductor substrate 10 including the formed trench, e.g., by chemical vapor deposition (CVD), and in this case, the deposition temperature is set at about 800-900° C. Subsequently, if necessary, the silicon dioxide film is annealed, e.g., at 900-1000° C., and then, the silicon dioxide film is planarized. This planarization allows exposure of an n-type MIS transistor formation region NTr and a p-type MIS transistor formation region PTr of the top surface of the semiconductor substrate 10 while allowing a portion of the silicon dioxide film deposited in the trench to remain. Thus, an insulative isolation region 11 is formed, and the n-type MIS transistor formation region NTr includes a first active region 10a corresponding to a region of the semiconductor substrate 10 surrounded by the isolation region 11. Similarly, the p-type MIS transistor formation region PTr also includes a second active region 10b corresponding to a region of the semiconductor substrate 10 surrounded by the isolation region 11.

Next, in a process step illustrated in FIGS. 4B1 and 4B2, p-type impurities, such as boron (B), are selectively implanted into the n-type MIS transistor formation region NTr of the semiconductor substrate 10, thereby forming a p-type well region 12a. Subsequently, n-type impurities, such as arsenic (As), are selectively implanted into the p-type MIS transistor formation region PTr of the semiconductor substrate 10, thereby forming an n-type well region 12b. Thereafter, an about 2-4-nm-thick silicon dioxide film is formed on the entire top surface of the semiconductor substrate 10, e.g., by thermal oxidation. Subsequently, an about 50-100-nm-thick polysilicon film is formed on the silicon dioxide film by CVD. Thereafter, the formed polysilicon film and the formed silicon dioxide film are patterned into desired gate electrode shapes by lithography and dry etching. Specifically, a gate insulating film 13 made of the silicon dioxide film is formed on each of the first active region 10a and the second active region 10b, and a gate electrode 14 made of the polysilicon film is formed on the gate insulating film 13. As described above, instead of silicon dioxide, a high dielectric constant insulating film may be used as a material of the gate insulating film 13. Furthermore, when a high dielectric constant insulating film is used as a material of the gate insulating film 13, a layered structure of a metal film and a silicon film is preferably used as the gate electrode 14.

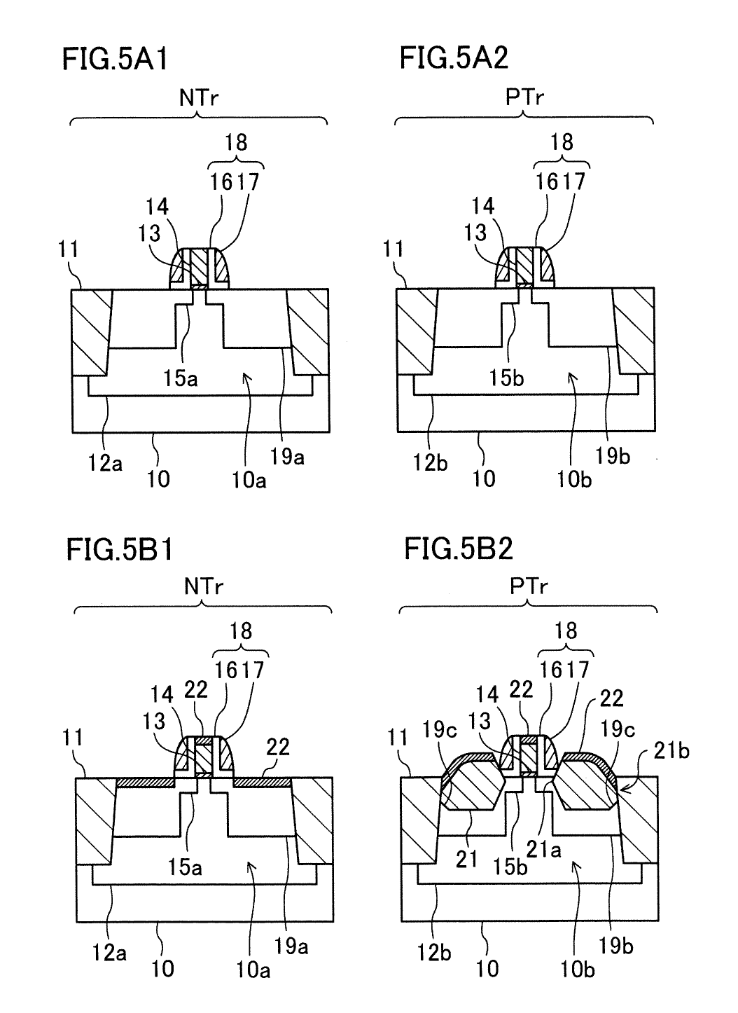

Next, in a process step illustrated in FIGS. 5A1 and 5A2, a first mask (not shown) is formed by lithography to cover the second active region 10b, and n-type impurities, such as arsenic, are implanted into the first active region 10a at an implantation energy of, e.g., 2-5 keV and a dose of, e.g., 1×10¹⁵-1×10¹⁶/cm² by using the formed first mask and the gate electrode 14 on the n-type MIS transistor formation region NTr as masks. Thus, n-type extension regions 15a each having a shallow junction depth are formed in regions of the first active region 10a located laterally outward of the corresponding gate electrode 14. Thereafter, the first mask is removed. Subsequently, a second mask (not shown) is formed by lithography to cover the first active region 10a, and p-type impurities, such as boron, are implanted into the second active region 10b at an implantation energy of, e.g., 2-5 keV and a dose of, e.g., 1×10¹⁵-1×10¹⁶/cm² by using the formed second mask and the gate electrode 14 on the p-type MIS transistor formation region PTr as masks. Thus, p-type extension regions 15b each having a shallow junction depth are formed in regions of the second active region 10b located laterally outward of the corresponding gate electrode 14. Thereafter, the second mask is removed. In this process step, the n-type extension regions 15a and the p-type extension regions 15b may be formed in any sequence. Subsequently, for example, an about 10-nm-thick silicon dioxide film and an about 50-nm-thick silicon nitride film are sequentially deposited on the entire surface of the semiconductor substrate 10 by CVD to cover the gate insulating films 13 and the gate electrodes 14. Thereafter, the deposited silicon nitride film and the deposited silicon dioxide film are subjected to anisotropic etching. Thus, sidewalls 18 are formed on both lateral side surfaces of each of the gate electrodes 14. Specifically, inner sidewalls 16 made of the silicon dioxide film are formed on both lateral side surfaces of the gate electrode 14 to each have an L-shaped cross section, and simultaneously, outer sidewalls 17 made of the silicon nitride film are formed on both lateral side surfaces of the gate electrode 14 with the inner sidewalls 16 interposed therebetween.

Subsequently, a third mask (not shown) is formed by lithography to cover the second active region 10b, and n-type impurities, such as arsenic, are implanted into regions of the first active region 10a located laterally outward of the corresponding sidewalls 18 at an implantation energy of, e.g., 30 keV and a dose of, e.g., 1×10¹⁶/cm² by using the formed third mask, and the gate electrode 14 and sidewalls 18 both on the n-type MIS transistor formation region NTr as masks. Thus, n-type source/drain regions 19a are formed in regions of the first active region 10a located laterally outward of the corresponding sidewalls 18 to each have a deeper junction depth than the n-type extension regions 15a. Thereafter, the third mask is removed. Subsequently, a fourth mask (not shown) is formed by lithography to cover the first active region 10a, and p-type impurities, such as boron, are implanted into regions of the second active region 10b located laterally outward of the corresponding sidewalls 18 at an implantation energy of, e.g., 30 keV and a dose of, e.g., 1×10¹⁶/cm² by using the formed fourth mask, and the gate electrode 14 and sidewalls 18 both on the p-type MIS transistor formation region PTr as masks. Thus, p-type source/drain regions 19b are formed in regions of the second active region 10b located laterally outward of the corresponding sidewalls 18 to each have a deeper junction depth than the p-type extension regions 15b. Thereafter, the fourth mask is removed. The n-type source/drain regions 19a and the p-type source/drain regions 19b may be formed in any sequence.

Next, in a process step illustrated in FIGS. 5B1 and 5B2, a hard mask formation film made of, e.g., silicon dioxide or silicon nitride is deposited on the entire surface of the semiconductor substrate 10, e.g., by CVD. For example, when, as illustrated in FIG. 2D, the outer sidewalls 17 are to remain, a hard mask formation film made of silicon dioxide is preferably formed, and when the outer sidewalls 17 are to be removed, and only the inner sidewalls 16 are to remain, a hard mask formation film made of silicon nitride is preferably formed. Thereafter, a hard mask made of the hard mask formation film is formed by lithography and etching to cover the first active region 10a corresponding to the n-type MIS transistor formation region NTr and have an opening pattern exposing the second active region 10b corresponding to the p-type MIS transistor formation region PTr. Subsequently, by using the formed hard mask, and the gate electrode 14 and sidewalls 18 both on the p-type MIS transistor formation region PTr as masks, the second active region 10b corresponding to the p-type MIS transistor formation region PTr is subjected to anisotropic dry etching using, e.g., hydrogen bromide (HBr) and carbon tetrafluoride (CF₄) as etching gases. Subsequently, while the hard mask remains, anisotropic wet etching is performed using a tetramethyl ammonium hydroxide (TMAH) solution as an etchant. Thus, recess regions 19c corresponding to recesses for forming p-type silicon alloy layers are formed in upper portions of the p-type source/drain regions 19b of the p-type MIS transistor formation region PTr. Although not shown, in this etching process step, a corner portion of each of upper ends of the isolation region 11 may be etched to form a round shape. The recess regions 19c formed by etching each have a wall surface with a {111} plane orientation of a silicon crystal, and a substantially central portion of the wall surface forms a Σ-shaped distal end portion protruding toward the corresponding gate electrode 14 below the corresponding sidewall 18. In this case, the depth of the distal end of the Σ-shaped distal end portion from the top surface of the semiconductor substrate 10, i.e., a portion of the top surface of the second active region 10b under the gate insulating film 13, is preferably about 18-23 nm, and here the depth is 20 nm.

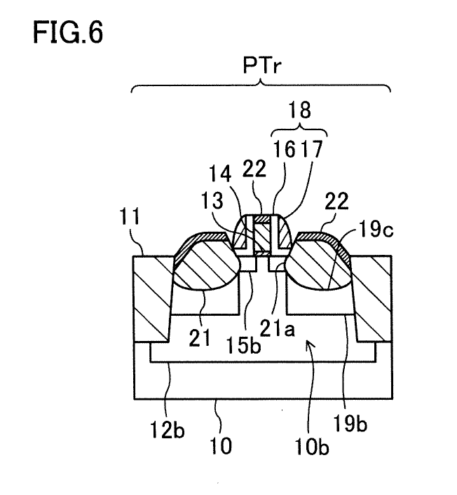

Anisotropic dry etching using HBr and CF₄ as etching gases, isotropic dry etching using CF₄ as an etching gas, and anisotropic wet etching using a TMAH solution as an etchant may be appropriately combined to form the recess regions 19c in the semiconductor substrate 10. For example, in order to form the recess regions 19c, only anisotropic dry etching using HBr and CF₄ may be performed, and alternatively, as in the above-described process step, anisotropic wet etching may be combined with anisotropic dry etching. Alternatively, isotropic dry etching using CF₄ may be combined with anisotropic dry etching. FIG. 6 illustrates a cross-sectional structure when anisotropic dry etching and isotropic dry etching are combined. In this case, anisotropic wet etching may be further performed. Specifically, for example, when a silicon substrate having a principal surface with a {100} plane orientation is used as the semiconductor substrate 10, an etching process in which the wall surface of the substrate including the Σ-shaped distal end portion has a {111} plane orientation may be used. The depth of each of the recess regions 19c is, e.g., about 50-80 nm.

Thereafter, while the hard mask remains, a p-type silicon alloy, such as silicon germanium (SiGe), is epitaxially grown in each of the recess regions 19c formed in the second active region 10b of the p-type MIS transistor formation region PTr, for example, by low pressure thermal CVD. When the silicon alloy is SiGe, germane (GeH₄) or any other gas can be used as a germanium (Ge) source gas. In this case, in order to dope the recess regions 19c with boron (B) which is a p-type impurity, the silicon alloy is preferably epitaxially grown with a supply of a diborane (B₂H₆) gas. Thus, p-type silicon alloy layers 21 are formed in the recess regions 19c, and the formed p-type silicon alloy layers 21 form portions of the second active region 10b, i.e., portions of the p-type source/drain regions 19b. The formed p-type silicon alloy layers 21 each have a thickness of about 120 nm, and the Ge concentration in each of the p-type silicon alloy layers 21 is about 20-30 weight percent (wt. %).

Here, in order to reduce the thickness of a portion of each of the p-type silicon alloy layers 21 at the interface between the p-type silicon alloy layer 21 and the isolation region 11, for example, the deposition rate during the growth may be decreased, and the supply of hydrogen chloride (HCl) may be increased. For example, a SiGe alloy is epitaxially grown under the conditions where the temperature is about 600-800° C., the flow rate of, e.g., GeH₄ which is a germanium (Ge) source gas is about 14-40 ml/min (standard state), and the flow rate of dichlorosilane is about 10-40 ml/min (standard state). The flow rate of the HCl gas is preferably in the range of 20-120 ml/min (standard state). In this embodiment, the temperature is 650° C., the flow rate of dichlorosilane is 25 ml/min (standard state), the flow rate of GeH₄ is 20 ml/min (standard state), and the flow rate of HCl is 100 ml/min (standard state). Thus, since the deposition rate of silicon germanium in the vicinity of the isolation region 11 decreases, this reduces the thickness of a portion of each of the p-type silicon alloy layers 21 at the interface between the p-type silicon alloy layer 21 and the isolation region 11.

Thereafter, the hard mask is removed, and the semiconductor substrate 10 is subjected to heat treatment at 800° C. for ten minutes. This heat treatment activates n-type and p-type impurities with which the extension regions 15a and 15b, the source/drain regions 19a and 19b, and the p-type silicon alloy layers 21 are doped.

Subsequently, an about 20-nm-thick nickel (Ni) film is deposited on the semiconductor substrate 10, e.g., by sputtering to cover the gate electrodes 14, the sidewalls 18, and the p-type silicon alloy layers 21. Thereafter, the semiconductor substrate 10 is subjected to heat treatment at 500° C. for ten minutes in a nitrogen atmosphere. Thus, nickel silicide (NiSi) films are formed in upper portions of the n-type source/drain regions 19a of the n-type MIS transistor formation region NTr, upper portions of the p-type source/drain regions (p-type silicon alloy layers 21) of the p-type MIS transistor formation region PTr, and upper portions of the gate electrodes 14. Subsequently, unreacted portions of the nickel film remaining on the isolation region 11 and the sidewalls 18 are removed using, e.g., an acid solution, ad then, heat treatment is performed to obtain a stable silicide. Thus, about 20-nm-thick silicide layers 22 are formed in upper portions of the n-type source/drain regions 19a, upper portions of the p-type silicon alloy layers 21, and upper portions of the gate electrodes 14. A feature of this embodiment is that a portion of an upper surface of each of the p-type silicon alloy layers 21 at the interface between the p-type silicon alloy layer 21 and the isolation region 11 is located below an upper surface of the second active region 10b. In this case, the p-type silicon alloy layers 21 are preferably formed such that the depth of an upper end 21b of a portion of each of the p-type silicon alloy layers 21 in contact with the isolation region 11 from the top surface of the isolation region 11 is about 10-60 nm.

Thereafter, although not shown, a stress insulating film inducing tensile stresses may be formed on at least the n-type MIS transistor formation region NTr of the semiconductor substrate 10.

As described above, in the method for fabricating a semiconductor device according to this embodiment, in the process step illustrated in FIG. 5B2, the p-type silicon alloy layers 21 are formed in the upper portions of the p-type source/drain regions 19b. Thus, compressive stresses are applied to a channel region of a p-type MIS transistor, thereby improving the carrier mobility. In addition, since stresses at the interface between each of the formed p-type silicon alloy layers 21 and the isolation region 11 are reduced, abnormal diffusion of dopants into the p-type MIS transistor is reduced, thereby reducing leakage current, in particular, leakage current during standby.

In this embodiment, a MIS transistor having a strained structure applying compressive stresses to a channel region of the MIS transistor is a p-type transistor; however, the MIS transistor according to the present disclosure is not limited to a p-type transistor. Specifically, tensile stresses may be applied to a channel region of an n-type MIS transistor. In this case, a silicon carbide (SiC) layer which is an alloy layer of silicon (Si) and carbon (C) can be used as an n-type silicon alloy layer forming each of the n-type source/drain regions.

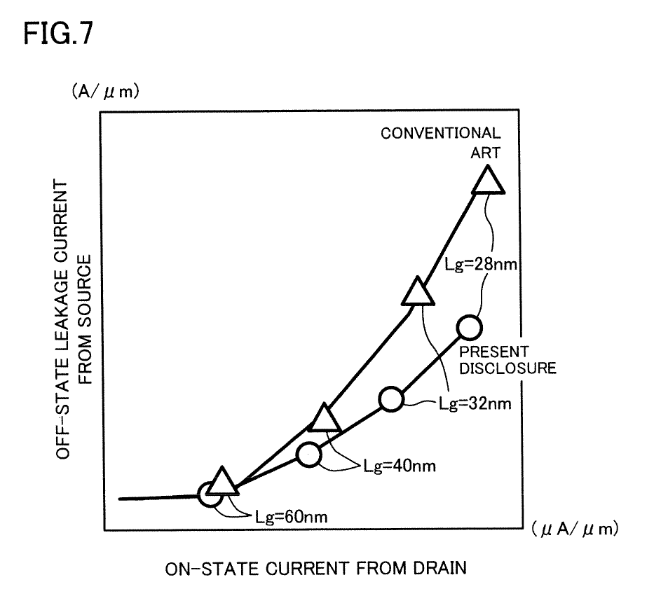

FIG. 7 illustrates electrical characteristics of a p-type MIS transistor according to a conventional example and the p-type MIS transistor according to this embodiment, i.e., the dependency of the relationship between an on-state current from a drain and an off-state leakage current from a source on the gate length (Lg). As illustrated in FIG. 7, when the gate length (Lg) is shorter than 60 nm, the off-state leakage current from the source tends to increase; however, in this embodiment, an increase in the off-state leakage current is reduced as compared with the conventional example.

The semiconductor device according to the present disclosure, and the method for fabricating the same provide a structure in which silicon alloy layers are formed in an corresponding active region to apply stresses to a corresponding channel region, can, thus, achieve both of an improvement in current driving capability and a reduction in leakage current, and are useful for, e.g., semiconductor devices forming system LSI circuits.

What is claimed is:

1. A semiconductor device comprising:
a first active region formed in a semiconductor region made of silicon, and surrounded by an isolation region; and
a first gate electrode formed on the first active region and the isolation region with a first gate insulating film interposed between the first gate electrode and a portion of the semiconductor region including the first active region and the isolation region, wherein
silicon alloy layers of a first conductivity type are formed in recesses formed in regions of the first active region located laterally outward of the first gate electrode, and
an upper end of a portion of each of the silicon alloy layers in contact with the isolation region is located below a portion of an upper surface of the first active region under the first gate insulating film.

2. The semiconductor device of claim 1, wherein
a side surface of each of the silicon alloy layers near the first gate electrode has a protrusion protruding below the first gate electrode, and
the upper end of the portion of each of the silicon alloy layers in contact with the isolation region is located below the protrusion.

3. The semiconductor device of claim 2, wherein
an upper surface of the semiconductor region has a {100} plane orientation, and
a surface of each of the silicon alloy layers forming the protrusion has a {111} plane orientation.

4. The semiconductor device of claim 1, wherein
the upper end of the portion of each of the silicon alloy layers in contact with the isolation region is located below one half of a depth of a thickest portion of the silicon alloy layer from a top surface of the silicon alloy layer.

5. The semiconductor device of claim 1, wherein
the silicon alloy layers are formed as first source/drain regions,
the semiconductor device further includes extension regions having the first conductivity type, and formed in regions of an upper portion of the first active region located laterally outward of the first gate electrode so as to be connected to the first source/drain regions, and
the upper end of the portion of each of the silicon alloy layers in contact with the isolation region is located below the extension regions.

6. The semiconductor device of claim 1, further comprising:
sidewalls formed on both side surfaces of the first gate electrode in a gate length direction, and made of an insulating film.

7. The semiconductor device of claim 1, wherein
the silicon alloy layers of the first conductivity type are made of p-type silicon germanium.

8. The semiconductor device of claim 7, further comprising:
a second active region formed in the semiconductor region with the isolation region interposed between the first and second active regions; and
a second gate electrode formed on the second active region and the isolation region with a second gate insulating film interposed between the second gate electrode and a portion of the semiconductor region including the second active region and the isolation region, wherein
second source/drain regions each made of an impurity diffusion layer of a second conductivity type are formed in an upper portion of the second active region.

9. The semiconductor device of claim 1, wherein
the silicon alloy layers of the first conductivity type are made of n-type silicon carbide.

10. The semiconductor device of claim 1, wherein
an upper surface of a thickest portion of each of the silicon alloy layers is located above the portion of the upper surface of the first active region under the first gate insulating film.
